(19) United States
(12) Patent Application Publication
(10) Pub. No.: US 2008/0153279 A1
(43) Pub. Date: Jun. 26, 2008

(54) Method For Manufacturing Semiconductor Device

(76) Inventor: Chang Youn Hwang, Icheon-Si (KR)

Correspondence Address: MARSHALL, GERSTEIN & BORUN LLP, 233 S. WACKER DRIVE, SUITE 6300, SEARS TOWER, CHICAGO, IL, 60606, US

(21) Appl. No.: 11/771,811

(22) Filed: Jun. 29, 2007

(30) Foreign Application Priority Data
Dec. 26, 2006 (KR) 10-2006-0134076

(51) Int. Cl. H01L 21/4763

(52) U.S. Cl. 438/607; 438/637; 257/E21.495

(57) ABSTRACT

A method for manufacturing a semiconductor device includes the steps of: forming a primary storage node contact plug at an upper part of the exposed landing plug at a lower part of the storage node contact hole; and filling the storage node contact hole with a conductive film to form a secondary storage node contact plug. In result, the size of a storage node contact may be increase to cause the contact resistance to decrease, without any loss of the interlayer insulating film to a cleaning solution.

### CROSS-REFERENCE TO RELATED APPLICATION

The priority benefit of Korean patent application number 10-2006-0134076, filed on Dec. 26, 2006, the entire disclosure of which is incorporated herein by reference, is claimed.

### BACKGROUND OF THE INVENTION

The invention relates generally to a semiconductor device and a method for manufacturing a semiconductor device and, more specifically, to a technique involved in a method for forming a storage node contact plug in a semiconductor device.

As semiconductor devices have become more highly integrated, storage node contacts have become reduced in size, causing contact resistance to increase. To resolve this, a wet etch process has been carried out as a post cleaning process during the formation of storage node contact holes, in an attempt to increase the size of storage node contact holes.

However, it has been found difficult to adapt such a method for increasing the size of storage node contact holes to up-to-date integrated semiconductor devices.

When an etch target is raised for a wet etch process to form storage node contact holes with an increased size, an interlayer insulating film remaining underneath the bit line of the device may be lost due to etching by an etching liquid. Moreover, in a pre-cleaning process that is carried out before filling a storage node contact hole with a conductive film, other interlayer insulating films remaining underneath the bit line maybe lost, resulting in a bridge between a storage node contact plug and a bit line.

### SUMMARY OF THE INVENTION

In view of the foregoing, the invention provides a method for manufacturing a semiconductor device capable of increasing the size of a storage node contact without losing interlayer insulating films that remain underneath a bit line during a cleaning process.

A method for manufacturing a semiconductor device according to the invention includes the steps of: forming a first interlayer insulating film over a semiconductor substrate defining a landing plug; forming spaced bit lines over the first interlayer insulating film; filling a gap between the bit lines to form a second interlayer insulating film; self-alignedly etching the second and first interlayer insulating films to form a storage node contact hole for exposing the landing plug; forming a primary storage node contact plug at an upper part of the exposed landing plug at a lower part of the storage node contact hole; and, filling the storage node contact hole with a conductive film to form a secondary storage node contact plug.

In an exemplary embodiment, the bit line formation step preferably includes forming a bit line spacer on sidewalls of the bit line, wherein the bit line spacer is preferably formed in a thickness range of 50 Å-150 Å, the second interlayer insulating film is preferably a spin on dielectric (SOD) film, and the second interlayer insulating film is preferably formed in a thickness range of 4000 Å-10000 Å.

Preferably, the storage node contact hole formation step is characterized by etching the second and first interlayer insulating films under conditions including a power range of 1000 W-2000 W, a pressure range of 15 mT-50 mT, and an atmosphere containing a gas selected from the group consisting of C₄F₈, C₅H₈, C₄F₆, CH₂F₂, Ar, O₂, Co, N₂, and mixtures thereof.

In the storage node contact formation step, an etching target of the second and the first interlayer insulating films preferably has a thickness ranging from 1000 Å to 2000 Å.

Preferably, the first storage node contact plug is thicker than the first interlayer insulating film remaining at a lower part of the storage node contact hole.

Moreover, the primary storage node contact plug formation step preferably includes a wet cleaning process, and the secondary storage node contact plug formation step preferably includes forming a storage node contact spacer on the sidewalls of the storage node contact hole.

Preferably, the storage node contact spacer formation step includes the steps of: forming a low pressure (LP) or other suitable nitride film over an entire surface of the resulting structure; selectively etching the nitride film; and performing a cleaning process.

Preferably, the nitride film is formed in a thickness range of 100 Å-300 Å, and is selectively etched, under conditions including a power range of 300 W-1000 W, a pressure range of 10 mT-30 mT, and an atmosphere containing a gas selected from the group consisting of CH₄, CHF₃, O₂, Ar, and mixtures thereof.

The conductive film preferably includes polysilicon, and is preferably formed in a thickness range of 1500 Å-3000 Å.

Therefore, according to the invention method for manufacturing a semiconductor device, the cleaning process does not proceed until the primary storage node contact plug is first formed at a lower part of the storage node contact hole. In this manner, the size of the storage node contact can be increased to cause the contact resistance to decrease, without any loss of the interlayer insulating film that remains at a lower part of the storage node contact hole.

Other objectives and advantages of the invention will be understood from the following description and the embodiments of the invention will be appreciated more clearly. Further, it will readily be seen that the objectives and advantages of the invention can be realized by the means and combinations recited in the claims.

### BRIEF DESCRIPTION OF THE DRAWINGS

FIGS. 1a through 1c show a manufacturing method of a semiconductor device according to a preferred embodiment of the invention.

### DESCRIPTION OF SPECIFIC EMBODIMENTS

Hereinafter, the invention is described in detail with reference to the accompanying drawings so that those skilled in the art can easily carry out the invention.

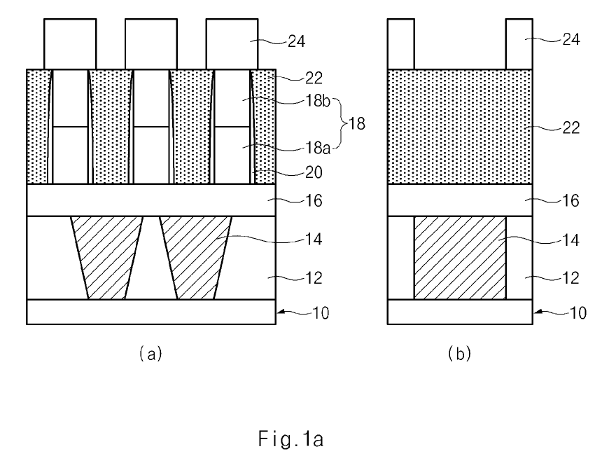

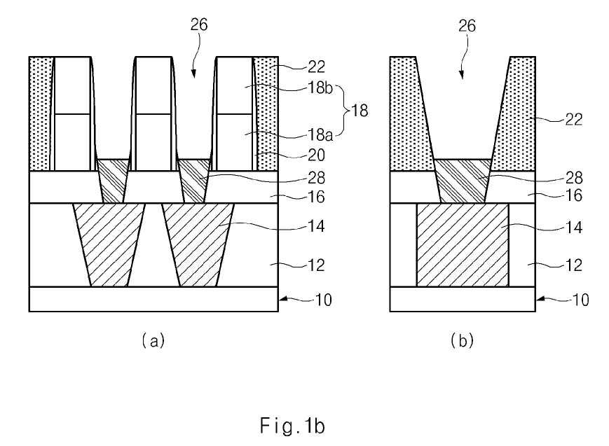

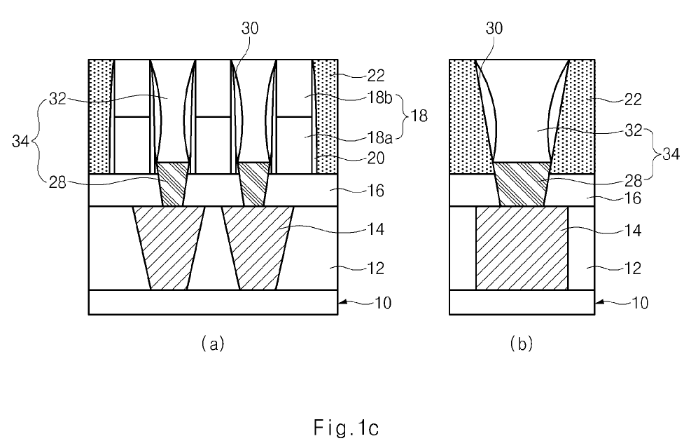

FIGS. 1a through 1c are cross-sectional views showing, in a stepwise fashion, a method for manufacturing a semiconductor device according to a preferred embodiment of the invention, in which (a) is a cross-sectional view being cut vertically with respect to the longitudinal direction of a bit line, and, (b) is a cross-sectional view being cut horizontally with respect to the longitudinal direction of a bit line in each figure.

Referring to FIG. 1a, a first interlayer insulating film 12 is formed at an upper part of a semiconductor substrate 10 provided with a designated lower structure.

A first photoresist (not shown) is coated over the first interlayer insulating film 12. The first photoresist is exposed and developed by using a landing plug contact mask to form a first photoresist pattern (not shown).

With the first photoresist pattern as an etching mask, the first interlayer insulating film 12 is selectively etched to form a landing plug contact hole (not shown).

After removing the first photoresist pattern, the landing plug contact hole is filled with a conductive film to complete the formation of a landing plug 14.

A second interlayer insulating film 16 is formed at an entire surface of the semiconductor substrate 10 having the landing plug 14 and the first interlayer insulating film 12.

A bit line tungsten layer, a bit line hard mask layer, a first hard mask layer, a first anti-reflective layer, and a second photoresist (not shown) are then sequentially formed at an upper part of the second interlayer insulating film 16. The bit line tungsten layer is preferably formed at a thickness between 300 Å and 1000 Å, the bit line hard mask layer is preferably formed at a thickness between 1000 Å and 2500 Å, the first hard mask layer (preferably an amorphous carbon layer) is preferably formed at a thickness between 1000 Å and 2000 Å, and the first anti-reflective layer (preferably a silicon oxy-nitride (SiON) layer) preferably has a thickness between 300 Å and 1000 Å (all ranges of thickness are inclusive of their end points).

The second photoresist is then exposed and developed with a mask defining the bit line, to form a second photoresist pattern (not shown).

With the second photoresist pattern as an etching mask, the first anti-reflective layer, the first hard mask layer, the bit line hard mask layer, and the bit line tungsten layer are etched to form a first anti-reflective layer pattern, a first hard mask layer pattern, a bit line hard mask layer pattern 18b, and a bit line tungsten layer pattern 18a, respectively. Here, the bit line hard mask layer is etched, preferably under conditions which include a power range of 300 W-1000 W, a pressure range of 20 mT-70 mT, and a gas atmosphere containing CH₄, CHF₃, O₂, Ar, or a mixture thereof.

The second photoresist pattern, the first anti-reflective layer pattern, and the first hard mask layer pattern are removed to form a bit line 18, which is a laminate structure of the bit line tungsten pattern 18a and the bit line hard mask layer pattern 18b.

Although not shown in FIG. 1(a), an upper barrier layer may be formed over the bit line 18. In such case, the barrier layer is preferably a Ti/TiN layer, preferably having a thickness of 100 Å-1000 Å.

A nitride film is then formed over the entire surface of the resulting structure. The nitride film is then selectively etched and cleaned to form a bit line spacer 20 on sidewalls of the bit line 18. The bit line spacer 20 preferably has a thickness of 50 Å-150 Å.

A third interlayer insulating film 22 is then formed over the entire surface of the resulting structure. The third interlayer insulating film 22 is preferably a spin on dielectric (SOD) film, preferably having a thickness of 4000 Å-10000 Å.

Next, a planarization process is performed is performed until the bit line hard mask pattern 18b is exposed, so that the third interlayer insulating film 22 can be planarized.

A second hard mask layer, a second anti-reflective layer, and a third photoresist are then sequentially formed at an upper part of the planarized third interlayer insulating film 22. The second hard mask layer is preferably an amorphous carbon layer.

The third photoresist is then exposed and developed with the storage node contact mask defining a storage node contact hole, to form a third photoresist pattern 24.

Referring to FIG. 1(b), with the third photoresist pattern 24 as an etching mask, the second hard mask layer, the second anti-reflective layer, the third interlayer insulating film 22, and the second interlayer insulating film 16 are self-alignedly etched, to form a storage node contact hole 26 for exposing the landing plug 14. The third interlayer insulating film 22 and the second interlayer insulating film 16 are then etched, preferably under conditions which include a power range of 1000 W-2000 W, a pressure range of 15 mT-50 mT, and a gas atmosphere containing C₄F₈, C₅H₈, C₄F₆, CH₂F₂, Ar, O₂, Co, N₂, or a mixture thereof. An etching target of the third interlayer insulating film 22 and the second interlayer insulating film 16 is preferably 1000 Å-2000 Å in thickness.

The third photoresist pattern 24 is then removed, and a cleaning process performed. At this time, the second anti-reflective layer and the second hard mask layer are also removed together.

A primary storage node contact plug 28 is formed at an upper part of the exposed landing plug 14 at a lower part of the storage node contact hole 26, preferably by a selective epitaxial growth (SEG) method. Here, the primary storage node contact plug 28 serves as a barrier layer for preventing the loss of the second interlayer insulating film 16 that remains at a lower part of the storage node contact hole 26 during a post wet cleaning process that precedes the formation of a secondary storage node contact plug. To this end, the primary storage node contact plug 28 is preferably thicker than the second interlayer insulating film 16 remaining at a lower part of the storage node contact hole 26.

The resultant structure then undergoes a wet cleaning process, so that residuals materials produced from an etch process may be removed, and the size of the contact hole 26 can be increased. At this time, the primary storage node contact plug 28 prevents a cleaning solution from infiltrating the second interlayer insulating film 16 remaining at the lower part of the storage node contact hole 26. In this way, the loss of the second interlayer insulating film 16 can be prevented.

Referring to FIG. 1c, a low pressure (LP) nitride film is then formed over the entire surface. The LP nitride film is preferably 100 Å-300 Å in thickness.

The LP nitride film is selectively etched and cleaned to form a storage node contact spacer 30 on sidewalls of the storage node contact hole 26. The LP nitride is preferably etched under conditions which include a power range of 300 W-1000 W, a pressure range of 10 mT-30 mT, and a gas atmosphere containing CH₄, CHF₃, O₂, Ar, or a mixture thereof.

The storage node contact hole 26 is filled with a conductive film to form a secondary storage node contact plug 32, leading to the completion of forming a storage node contact plug 34. The conductive film is preferably a polysilicon film, preferably with a thickness in a range between 1500 Å and 3000 Å.

The top of the conductive layer is planarized through a planarization process and, at the same time, is separated from the neighboring storage node contact plug 34.

While the invention has been described with respect to the specific embodiments, various changes and modifications may be made without departing from the spirit and scope of the invention as defined in the following claims.

What is claimed is:

1. A method for manufacturing a semiconductor device, comprising the steps of:
forming a first interlayer insulating film over a semiconductor substrate defining a landing plug;
forming spaced bit lines having sidewalls over the first interlayer insulating film;
filling a gap between the bit lines to form a second interlayer insulating films;
self-alignedly etching the second and first interlayer insulating films to form a storage node contact hole exposing the landing plug;
forming a primary storage node contact plug at an upper part of the exposed landing plug at a lower part of the storage node contact hole; and
filling the storage node contact hole with a conductive film to form a secondary storage node contact plug.

2. The method of claim 1, wherein the bit line formation step includes forming a bit line spacer on sidewalls of the bit lines.

3. The method of claim 2, comprising forming the bit line spacer in a thickness range of 50 Å-150 Å.

4. The method of claim 1, wherein the second interlayer insulating film comprises a spin on dielectric (SOD) film.

5. The method of claim 1, comprising forming the second interlayer insulating film in a thickness range of 4000 Å-10000 Å.

6. The method of claim 1, wherein the storage node contact hole formation step comprises etching the second and first interlayer insulating films under conditions including a power range of 1000 W-2000 W, a pressure range of 15 mT-50 mT, and an atmosphere containing a gas selected from the group consisting of C₄F₈, C₅H₈, C₄F₆, CH₂F₂, Ar, O₂, Co, N₂, and mixtures thereof.

7. The method of claim 1, wherein, at the storage node contact formation step, an etching target of the second and the first interlayer insulating film has a thickness ranging from 1000 Å to 2000 Å.

8. The method of claim 1, wherein the first storage node contact plug is thicker than the first interlayer insulating film remaining at a lower part of the storage node contact hole.

9. The method of claim 1, wherein the primary storage node contact plug formation step includes a wet cleaning process.

10. The method of claim 1, wherein the secondary storage node contact plug formation step includes forming a storage node contact spacer on the sidewalls of the storage node contact hole.

11. The method of claim 10, wherein the storage node contact spacer formation step comprises the steps of:
forming a low pressure (LP) nitride film over an entire surface of the resulted structure;
selectively etching the LP nitride film; and
performing a cleaning process.

12. The method of claim 11, comprising forming the LP nitride in a thickness range of 100 Å-300 Å.

13. The method of claim 11, wherein the LP nitride film is selectively etched under conditions including a power range of 300 W-1000 W, a pressure range of 10 mT-30 mT, and an atmosphere containing a gas selected from the group consisting of CH₄, CHF₃, O₂, Ar, and mixtures thereof.

14. The method of claim 1, wherein the conductive film is a polysilicon film.

15. The method of claim 1, comprising forming the conductive film in a thickness range of 1500 Å-3000 Å.

16. The method of claim 1, comprising forming the primary storage node contact plug by performing a selective epitaxial growth method.
